(19) United States
(12) Patent Application Publication
(10) Pub. No.: US 2025/0170613 A1
(43) Pub. Date: May 29, 2025

(54) ULTRASONIC TRANSDUCER

(71) Applicant: Unictron Technologies Corporation, Hsin-Chu (TW)

(72) Inventors: Lung Chen, Taipei City (TW); San-Tang Chen, Taoyuan City (TW); Sheng-Yen Tseng, Taoyuan City (TW); Yi-Ting Su, Hsinchu City (TW)

(73) Assignee: Unictron Technologies Corporation, Hsin-Chu (TW)

(21) Appl. No.: 18/404,777

(22) Filed: Jan. 4, 2024

(30) Foreign Application Priority Data
Nov. 29, 2023 (TW) 112146244

(51) Int. Cl. B06B 1/06; H10N 30/88

(52) U.S. Cl. CPC B06B 1/067; B06B 1/0681; H10N 30/883; B06B 2201/55

(57) ABSTRACT

An ultrasonic transducer, including a piezoelectric element with an upper surface and a lower surface opposite to each other through the piezoelectric element and a lateral surface connecting the upper surface and the lower surface, a first acoustic matching layer with a first surface and a second surface opposite to each other through the first acoustic matching layer, and the first surface of the first acoustic matching layer is connected with the upper surface of the piezoelectric element, and a second acoustic matching layer with a third surface and a fourth surface opposite to each other through the second acoustic matching layer, and the third surface of the second acoustic matching layer is connected with the second surface of the first acoustic matching layer, and the glass transition temperature of the second acoustic matching layer is smaller than the glass transition temperature of the first acoustic matching layer.

### BACKGROUND OF THE INVENTION

### 1. Field of the Invention

The present invention relates generally to an ultrasonic transducer, and more specifically, to an ultrasonic transducer with dual acoustic matching layers.

### 2. Description of the Prior Art

Ultrasonic transducer may be used in short-range object detection. Through calculation of the time of flight (ToF) between emitting waves and reflected waves from objects, the distance between the ultrasonic transducer and detected object may be obtained. In the field of ultrasonic detection, the types and properties of objects to be detected is not quite restrictive. Solid, liquid or particle with various surface colors, transparencies and hardness may all be detected by using ultrasonic transducer. Therefore, the ultrasonic transducer nowadays is widely used in the fields like parking sensors, level sensors, multiple sheet detection, flow meter and edge position detection.

The main component of an ultrasonic transducer is piezoceramics element, for example, the ceramic element made of lead zirconate titanate (PZT) material with two opposite surfaces coated with conductive layers to apply high-frequency alternating current signal in the operation, so that the piezoceramics would generate high-frequency vibration. This high-frequency vibration is a kind of wave energy. It may be in a form of ultrasonic wave, i.e. ultrasonic vibration, if its wavelength falls within the range of ultrasound. However, in order to transmit the generated ultrasonic waves from the piezoceramics into air, the acoustic impedances of piezoceramics and air should be matched.

The formula to calculate the acoustic impedance (Z) is Z=ρ·c (ρ=material density, c=ultrasound velocity). The acoustic impedance of piezoceramics is about 30-35 MRayl (10⁶ kg/m²·S), while the acoustic impedance of air is about 430 Rayl (kg/m²·S). Since there is a huge gap between the acoustic impedances of piezoceramics and air, the ultrasonic energy generated by the piezoelectric can't be transmitted to air. Therefore, the acoustic matching layer becomes a critical component in ultrasonic transducers. The acoustic matching layer is designed to be set between the piezoceramics and air to match the acoustic impedances thereof, so that the ultrasonic wave may be effectively transmitted to air. The ideal value of acoustic impedance for the acoustic matching layer used in ultrasonic air transducer is √(35 M·430) Rayl, i.e. about 0.12 MRayl. However, it is difficult to find a durable material with acoustic impedance lower than 1 MRayl in nature. Therefore, commonly-used material of the acoustic matching layer in transducer industry is composite material with mixed polymer resin and hollow glass particles, to achieve lower acoustic impedance, and at the same time, provide better weatherability and reliability. In order to operate ultrasonic transducer smoothly at higher temperatures, acoustic matching layer with higher glass transition temperature is usually used in transducer industry, and it is therefore usually provided with higher hardness, causing worse weatherability for the ultrasonic transducer. Accordingly, the industry still needs to further develop and improve the acoustic matching layer, in hope of enhancing its weatherability and reliability in all kinds of application environment.

### SUMMARY OF THE INVENTION

The summary of present invention is provided in following paragraphs to assist readers having a better understanding of the subject matter of present invention. The summary is presented to be not exhaustive and/or exclusive to the features and advantages of the present invention, and doesn't intend to list all crucible or essential elements or to limit the scope of present invention. With the purpose just to provide certain concepts relied therein to be described through embodiments in a simplified form, detailed features and advantages of the invention will become apparent in the following description, from the drawings, and from the claims.

In the light of the aforementioned current situation of conventional skill, the present invention hereby provides an ultrasonic transducer with a piezoelectric element and dual acoustic matching layers, wherein the glass transition temperature of second acoustic matching layer is smaller than the glass transition temperature of first acoustic matching layer to improve the performance of ultrasonic transducer at high temperatures. In addition, in order to enhance the weatherability, the hardness of second acoustic matching layer may be designedly smaller than the hardness of first acoustic matching layer.

One aspect of the present invention is to provide an ultrasonic transducer, with structure including: a piezoelectric element with an upper surface and a lower surface opposite to each other through the piezoelectric element and a lateral surface connecting the upper surface and the lower surface; a first acoustic matching layer with a first surface and a second surface opposite to each other through the first acoustic matching layer, and the first surface of first acoustic matching layer is connected with the upper surface of piezoelectric element; and a second acoustic matching layer with a third surface and a fourth surface opposite to each other through the second acoustic matching layer, and the third surface of second acoustic matching layer is connected with the second surface of first acoustic matching layer, and a glass transition temperature of the second acoustic matching layer is smaller than a glass transition temperature of the first acoustic matching layer.

Another aspect of the present invention is to provide an ultrasonic transducer, with structure including: a piezoelectric element with an upper surface and a lower surface opposite to each other through the piezoelectric element and a lateral surface connecting the upper surface and the lower surface; a barrel-shaped carrier, wherein the barrel-shaped carrier includes an opening, a bottom opposite to the opening and a body connecting the opening and the bottom, and the barrel-shaped carrier is provided with an inner surface and an outer surface opposite to each other through the barrel-shaped carrier, and the inner surface of barrel-shaped carrier is connected with the upper surface of piezoelectric element; a first acoustic matching layer with a first surface and a second surface opposite to each other through the first acoustic matching layer, and the first surface of first acoustic matching layer is connected with the outer surface of the barrel-shaped carrier; and a second acoustic matching layer with a third surface and a fourth surface opposite to each other through the second acoustic matching layer, and the third surface of second acoustic matching layer is connected with the second surface of first acoustic matching layer, and a glass transition temperature of the second acoustic matching layer is smaller than a glass transition temperature of the first acoustic matching layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute a part of this specification. The drawings illustrate some of the embodiments and, together with the description, serve to explain their principles. In the drawings:

FIG. 1 is a cross-sectional view illustrating one mode of the ultrasonic transducer in accordance with one embodiment of the present invention;

FIG. 2 is a cross-sectional view illustrating another mode of the ultrasonic transducer in accordance with one embodiment of the present invention;

FIG. 3 is a cross-sectional view illustrating still another mode of the ultrasonic transducer in accordance with one embodiment of the present invention;

FIG. 4 is a cross-sectional view illustrating still another mode of the ultrasonic transducer in accordance with one embodiment of the present invention; and

FIG. 5 is a cross-sectional view illustrating still another mode of the ultrasonic transducer in accordance with one embodiment of the present invention.

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

In following detailed description of the present invention, reference is made to the accompanying drawings which form a part hereof and is shown by way of illustration and specific embodiments in which the invention may be practiced. These embodiments are described in sufficient details to enable those skilled in the art to practice the invention. Dimensions and proportions of certain parts of the drawings may have been shown exaggerated or reduced in size, for the sake of clarity and convenience in the drawings. Other embodiments may be utilized and structural, logical, and electrical changes may be made without departing from the scope of the present invention. The following detailed description, therefore, is not to be taken in a limiting sense, and the scope of the present invention is instead defined by the appended claims.

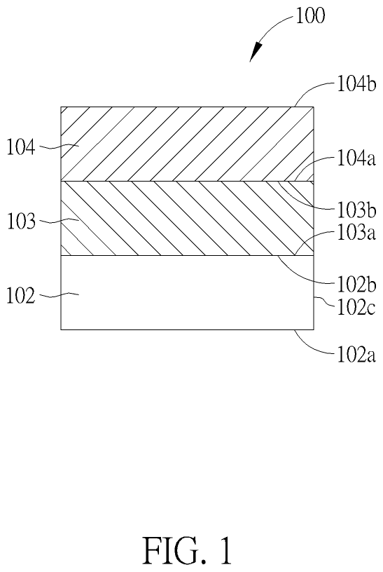

First, please refer to FIG. 1, which is a cross-sectional view illustrating one mode of the ultrasonic transducer 100 in accordance with one embodiment of the present invention. In this embodiment, the ultrasonic transducer 100 includes a piezoelectric element 102 with a lower surface 102a and an upper surface 102b opposite to each other through the piezoelectric element 102 and a lateral surface 102c connecting the upper surface 102b and the lower surface 102a. The piezoelectric element 102 may include solid piezoelectric material in the shape of square, rectangle, polygon or circle, or annular piezoelectric material, or piezoelectric material made of multilayer ceramic processing, or a piezoelectric material with grooves. These piezoelectric materials may include leaded piezoelectric material like Pb(ZrTi)O₃, PbTiO₃, or lead-free piezoelectric material like BaTiO₃, (NaK)NbO₃, with an acoustic impedance about 30-35 MRayl, much greater than the acoustic impedance of air (about 430 Rayl), thus an acoustic matching layer is required to match the acoustic impedances in these two mediums. The conductive layer on the piezoelectric element 102 may be connected with conductive wires (not shown) to electrically connect external high-frequency alternating current signal to the piezoelectric element 102 and generate high-frequency vibration in order to emit ultrasonic waves. The ultrasonic transducer 100 further includes a first acoustic matching layer 103 with a first surface 103a and a second surface 103b opposite to each other through the first acoustic matching layer 103, wherein the first surface 103a of first acoustic matching layer 103 is bonded on the upper surface 102b of piezoelectric element 102 and directly contacts therewith. In the embodiment of present invention, the thickness of first acoustic matching layer 103 in a direction perpendicular to the upper surface 102a of the piezoelectric element 102 is approximately equal to ¼ wavelength of the ultrasonic wave emitted by the piezoelectric element 102 in the first acoustic matching layer 103 at an operating frequency, so as to achieve optimal ultrasonic transmission.

With regard to material, the material of first acoustic matching layer 103 may be organic polymer materials or composite materials made of organic polymer materials mixing with hollow particles or solid particles. The organic polymer material includes epoxy, vinyl ester resin, acrylic resin, UV resin or cyanate ester resin. The hollow particles or solid particles may be hollow glass particles or solid glass particles, as a filler to be uniformly distributed in the organic polymer materials to adjust total density of the first acoustic matching layer 103. The density of hollow glass particles is between 0.08 g/cm³ to 0.8 g/cm³. Since the acoustic impedance is proportional to the density of material, the lower the density of the first acoustic matching layer 103 is, the lower the acoustic impedance may be obtained, so that better acoustic matching may be achieved in the operation. The first acoustic matching layer 103 may be modulated with different densities by adding the glass particles with different percentage by volume into the organic polymer materials and undergo mixing, degasing and curing treatment.

Refer still to FIG. 1. The ultrasonic transducer 100 further includes a second acoustic matching layer 104 with a third surface 104a and a fourth surface 104b opposite to each other through the second acoustic matching layer 104, and the third surface 104a is connected with the second surface 103b of the first acoustic matching layer 103. The second acoustic matching layer 104 is bonded tightly on the piezoelectric element 102 through the first acoustic matching layer 103 to form a dual-layered acoustic matching structure. One advantage of dual-layered acoustic matching structure is that it can significantly increase the bandwidth of ultrasonic transducer. In the embodiment of present invention, the material of second acoustic matching layer 104 may be organic polymer materials or composite materials made of organic polymer materials mixing with hollow particles or solid particles. The organic polymer material includes epoxy, vinyl ester resin, UV resin, polyurethane, silicone, acrylic resin or cyanate ester resin. The hollow particles or solid particles may be hollow glass particles or solid glass particles, as a filler to be uniformly distributed in the organic polymer materials to adjust total density of the second acoustic matching layer 104. The density of hollow glass particles is between 0.08 g/cm³ to 0.8 g/cm³. Since the acoustic impedance is proportional to the density of material, the lower the density of the second acoustic matching layer 104 is, the lower the acoustic impedance may be obtained, so that better acoustic matching may be achieved in the operation. The second acoustic matching layer 104 may be modulated with different densities by adding the glass particles with different percentage by volume into the organic polymer materials and undergo mixing, degasing and curing treatment.

In general, acoustic matching layer with higher glass transition temperature (T_{g}) would also have higher hardness, making the ultrasonic transducer suffer poor weatherability, susceptible to deterioration and embrittlement in temperature cycling of external environment. Accordingly, in the present invention, in order to make the ultrasonic transducer can operate normally at higher temperatures without compromise its weatherability, the glass transition temperature of first acoustic matching layer 103 in ultrasonic transducer 100 is designedly larger than 60° C., and the glass transition temperature of second acoustic matching layer 104 is designedly smaller than the glass transition temperature of first acoustic matching layer 103. Furthermore, the hardness of second acoustic matching layer 104 is designedly smaller than the hardness of first acoustic matching layer 103. In actual implementation, the glass transition temperature and hardness of the two acoustic matching layers may be controlled by choosing specific thermosetting polymer resin material. With this design, since the first acoustic matching layer 103 closer to the interior of transducer has higher glass transition temperature, the ultrasonic transducer may operate at higher temperatures, and since the second acoustic matching layer 104 closer to outer side has lower glass transition temperature and smaller hardness, it may adapt to the change of external temperature environment and achieve the purpose of enhanced weatherability, which is one great advantage of present invention.

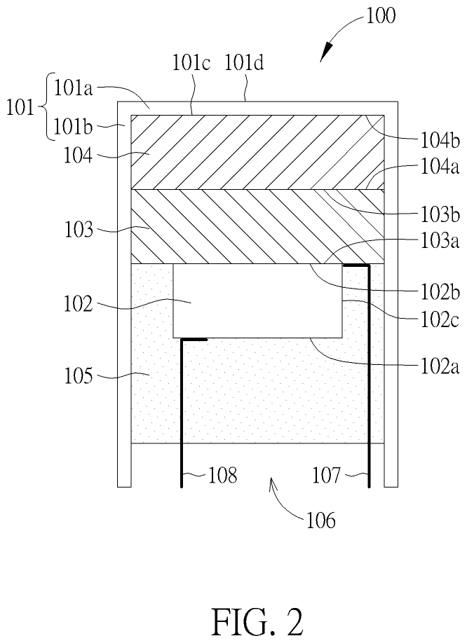

Please refer next to FIG. 2. The ultrasonic transducer 100 of present invention may also be set in a barrel-shaped carrier 101. As shown in FIG. 2, the barrel-shaped carrier 101 includes an opening 106, a bottom 101a opposite to the opening 106 and a body 101b connecting the opening 106 and the bottom 101a, and the barrel-shaped carrier is further provided with an inner surface 101c and an outer surface 101d opposite to each other through the barrel-shaped carrier 101, wherein the piezoelectric element 102, the first acoustic matching layer 103 and the second acoustic matching layer 104 are set in the barrel-shaped carrier 101, and the fourth surface 104b of second acoustic matching layer 104 is bonded with the inner surface 101c of the bottom 101a of barrel-shaped carrier 101 and directly connected therewith. This design makes the ultrasonic transducer more adaptive to harsh external environment and protects the acoustic matching layer from damage. The material of barrel-shaped carrier 101 may be selected from metal materials of following group or the combination thereof: aluminum (Al), titanium (Ti), copper (Cu), stainless steel, or is selected from non-metal materials of following group or the combination thereof: glass, acrylic, polytetrafluoroethylene (PTFE), polyvinylidene difluoride (PVDF), polypropylene (PP), polyethylene (PE), polyvinyl chloride (PVC), polybutylene terephthalate (PBT), acrylonitrile butadiene styrene (ABS), polyphenylene sulfide (PPS), liquid-crystal polymer (LCP) or polyether ether ketone (PEEK).

Refer still to FIG. 2. In addition to the components above, the ultrasonic transducer 100 of present invention may further include a damping element. As shown in FIG. 2, the ultrasonic transducer 100 further includes a damping element 105 encapsulating the piezoelectric element 102 and exposed from the opening 106 of barrel-shaped carrier 101. In other embodiment, the damping element 105 may encapsulate the first acoustic matching layer 103 and/or the second acoustic matching layer 104 in the barrel and fill up the space between first acoustic matching layer 103 and/or second acoustic matching layer 104 and barrel-shaped carrier 101. In this way, the damping element 105 may effectively buffer to lower the ringing of the ultrasonic transducer under high-frequency vibration in the operation of piezoelectric element 102. The ultrasonic transducer 100 may include a first conductive wire 107 connecting the upper surface 102b of piezoelectric element 102 and a second conductive wire 108 connecting the lower surface 102a of piezoelectric element 102. The first conductive wire 107 and second conductive wire 108 may extend outside from the opening 106 of barrel-shaped carrier 101 through the damping element 105 to electrically connect external high-frequency alternating current signal. With regard to material, the material of damping element 105 may be fibrous elastomer, including specifically silicone, rubber, ethylene vinyl acetate (EVA), styrene elastomer, polyester elastomer, olefin elastomer, thermoplastic vulcanized rubber (TPV), thermoplastic polyurethane (TPU), epoxy, wood cork, polyester staple, wool felt, glass fiber or foam.

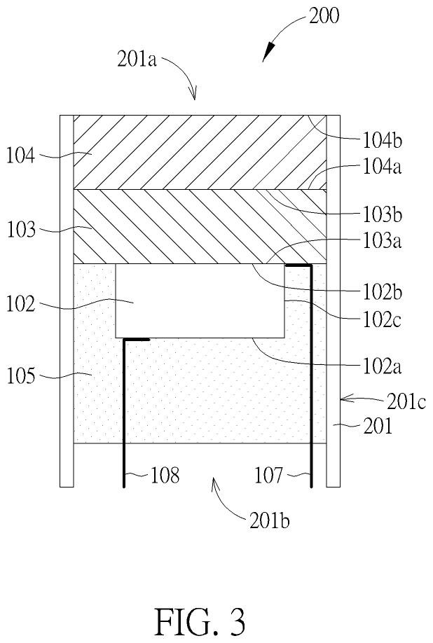

Please refer to FIG. 3, which is a cross-sectional view illustrating still another mode of the ultrasonic transducer in accordance with one embodiment of the present invention. In the embodiment of FIG. 2, the piezoelectric element and acoustic matching layer are set on the barrel-shaped carrier, while in this embodiment, the piezoelectric element and acoustic matching layer of ultrasonic transducer 200 are set on a tubular carrier 201. As shown in the figure, the tubular carrier 201 is provided with an upper opening 201a, a lower opening 201b opposite to the upper opening 201a and a body connecting the upper opening 201a and lower opening 201b, wherein the tubular carrier 201 surrounds the piezoelectric element 102, damping element 105, first acoustic matching layer 103 and second acoustic matching layer 104, and the inner surface of tubular carrier 201 may be connected with the damping element 105, first acoustic matching layer 103 and second acoustic matching layer 104 to fixed on the tubular carrier 201. In this way, the second acoustic matching layer 104 and damping element 105 are exposed respectively from the upper opening 201a and the lower opening 201b of tubular carrier 201. With regard to material, the material of tubular carrier 114 may be selected from metal materials of following group or the combination thereof: aluminum (Al), titanium (Ti), copper (Cu), stainless steel, or is selected from non-metal materials of following group or the combination thereof: glass, acrylic, polytetrafluoroethylene (PTFE), polyvinylidene difluoride (PVDF), polypropylene (PP), polyethylene (PE), polyvinyl chloride (PVC), polybutylene terephthalate (PBT), acrylonitrile butadiene styrene (ABS), polyphenylene sulfide (PPS), liquid-crystal polymer (LCP) or polyether ether ketone (PEEK), etc. Other detailed features of the ultrasonic transducer in this embodiment are identical to the ultrasonic transducer shown in FIG. 2, redundant description is therefore herein omitted.

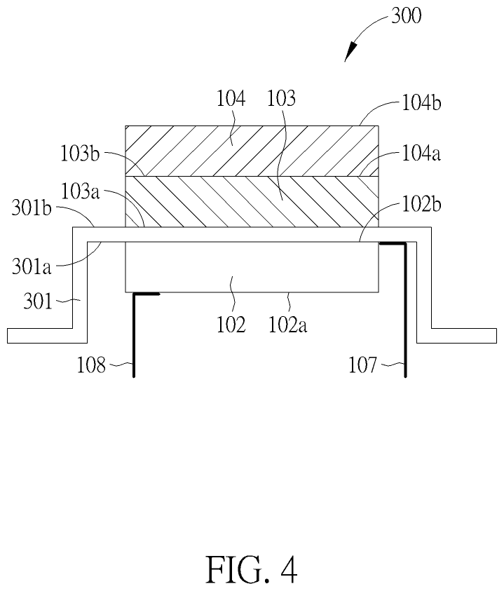

Please refer next to FIG. 4, which is a schematic cross-sectional view illustrating still another mode of the ultrasonic transducer in accordance with one embodiment of the present invention. In the embodiment of FIG. 2 and FIG. 3, the piezoelectric element and acoustic matching layer are both set in the inner accommodating space of the carrier, while in this embodiment, the piezoelectric element and acoustic matching layer are set respectively inside and outside the carrier. As shown in FIG. 4, similarly, a barrel-shaped carrier 301 is provided, with the piezoelectric element 102 of ultrasonic transducer 300 is set in the inner accommodating space of the barrel-shaped carrier 301, wherein the upper surface 102b of piezoelectric element 102 and inner surface 301a of the bottom of barrel-shaped carrier 301 are connected and fixed thereon. The first acoustic matching layer 103 is set outside the barrel-shaped carrier 301, wherein the first surface 103a of first acoustic matching layer 103 and outer surface 301b of the bottom of barrel-shaped carrier 301 are connected and fixed thereon, and the third surface 104a of second acoustic matching layer 104 and the second surface 103b of the first acoustic matching layer 103 are connected and fixed thereon. In addition, in this embodiment, the material of barrel-shaped carrier 301 may be conductive metal like aluminum (Al), titanium (Ti), copper (Cu), stainless steel, etc., and the first conductive wire 107 may be electrically connected directly on the inner surface 301a or outer surface 301b of the barrel-shaped carrier 301, while the second conductive wire 108 is connected with the lower surface 102a of piezoelectric element 102, so as to achieve the purpose of connecting external high-frequency alternating current signal. Other detailed features of the ultrasonic transducer in this embodiment are identical to the ultrasonic transducer shown in FIG. 2, redundant description is therefore herein omitted.

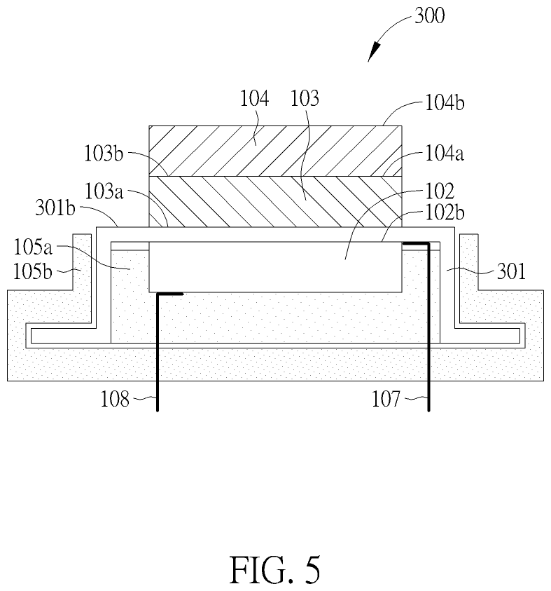

Refer next to FIG. 5, which is a schematic cross-sectional view illustrating still another mode of the ultrasonic transducer in accordance with one embodiment of the present invention. The embodiment of FIG. 5 is similar to the embodiment of FIG. 4, with difference that the ultrasonic transducer 300 in the embodiment of FIG. 5 is further provided with two damping elements. As shown in FIG. 5, a first damping element 105a is set in the body of barrel-shaped carrier 301. The first damping element 105a is set in the space between the barrel-shaped carrier 301 and piezoelectric element 102 and encapsulates the piezoelectric element 102. In this way, the first damping element 105a may effectively buffer to lower the ringing of the ultrasonic transducer under high-frequency vibration in the operation of piezoelectric element 102. Furthermore, in the embodiment of present invention, there might be air gaps between the first damping element 105a and the piezoelectric element 102. The presence of air gap may provide incomplete sealing between the first damping element 105a and the piezoelectric element 102, so as to provide space for the vibration of piezoelectric element 102, providing both the effects of vibrating and damping as well as improve the reliability of piezoelectric element. In addition, a second damping element 105b may be further provided to encapsulate the first damping element 105a and barrel-shaped carrier 301 in order to provide further damping effect. As shown in FIG. 5, the second damping element 105b may encapsulate entire barrel-shaped carrier 301, including its sidewalls and lateral portions, the conductive surfaces of first acoustic matching layer 103 and second acoustic matching layer 104 are exposed from the second damping element 105b. The second damping element 105b may also fix the first conductive wire 107 and second conductive wire 108.

With regard to material, the damping coefficients of first damping element 105a and second damping element 105b may be different, and the hardness of first damping element 105a and second damping element 105b may also be different. For example, the hardness of first damping element 105a is smaller than or equal to the hardness of second damping element 105b, so that these two damping elements with different types and configurations may further effectively damping the piezoceramic element 102 in high-frequency vibration and reset it into static state. This design facilitates the operation of ultrasonic transducer and provides better damping effect. The material of first damping element 105a may be porous or fibrous elastomer, including specifically silicone, rubber, ethylene vinyl acetate (EVA), styrene elastomer, polyester elastomer, olefin elastomer, thermoplastic vulcanized rubber (TPV), thermoplastic polyurethane (TPU), epoxy, wood cork, polyester staple, wool felt, glass fiber or foam. The material of second damping element 105b may include styrene elastomer, polyester elastomer, olefin elastomer, thermoplastic vulcanized rubber (TPV), thermoplastic polyurethane (TPU) or epoxy. Other detailed features of the ultrasonic transducer in this embodiment are identical to the ultrasonic transducer shown in FIG. 4, redundant description is therefore herein omitted.

The ultrasonic transducer of present invention made according to the aforementioned structures and designs features dual acoustic matching layers, wherein the glass transition temperature of first acoustic matching layer is larger than the glass transition temperature of second acoustic matching layer, and the hardness of first acoustic matching layer is larger than the hardness of second acoustic matching layer, so as to increase operable temperature of the transducer without compromise its weatherability to external temperature environment, which is an invention provided with both novelty and practicality.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An ultrasonic transducer, comprising:
a piezoelectric element with an upper surface and a lower surface opposite to each other through said piezoelectric element and a lateral surface connecting said upper surface and said lower surface;
a first acoustic matching layer with a first surface and a second surface opposite to each other through said first acoustic matching layer, and said first surface of said first acoustic matching layer is connected with said upper surface of said piezoelectric element; and
a second acoustic matching layer with a third surface and a fourth surface opposite to each other through said second acoustic matching layer, and said third surface of said second acoustic matching layer is connected with said second surface of said first acoustic matching layer, and a glass transition temperature of said second acoustic matching layer is smaller than a glass transition temperature of said first acoustic matching layer.

2. The ultrasonic transducer of claim 1, wherein said glass transition temperature of said first acoustic matching layer is larger than 60° C., and a hardness of said first acoustic matching layer is larger than a hardness of said second acoustic matching layer.

3. The ultrasonic transducer of claim 1, further comprising a first conductive wire connecting said upper surface of said piezoelectric element and a second conductive wire connecting said lower surface of said piezoelectric element.

4. The ultrasonic transducer of claim 1, further comprising a damping element, wherein damping said element encapsulates said piezoelectric element and/or said first acoustic matching layer and/or said second acoustic matching layer.

5. The ultrasonic transducer of claim 4, further comprising a barrel-shaped carrier, wherein said barrel-shaped carrier is provided with an opening, a bottom opposite to said opening and a body connecting said opening and said bottom, and said damping element, said piezoelectric element, said first acoustic matching layer and said second acoustic matching layer are set in said barrel-shaped carrier, and said second acoustic matching layer is connected with said bottom.

6. The ultrasonic transducer of claim 5, wherein a cross-section of said barrel-shaped carrier is in a shape of square, rectangle, circle or polygon.

7. The ultrasonic transducer of claim 4, further comprising a tubular carrier, wherein said tubular carrier is provided with an upper opening, a lower opening opposite to said upper opening and a body connecting said upper opening and said lower opening, and said tubular carrier surrounds said damping element and/or said first acoustic matching layer and/or said second acoustic matching layer, and said second acoustic matching layer is exposed from said upper opening of said tubular carrier.

8. The ultrasonic transducer of claim 7, wherein a cross-section of said tubular carrier is in a shape of square, rectangle, circle or polygon.

9. The ultrasonic transducer of claim 1, wherein said first acoustic matching layer comprises organic polymer materials or comprises a composite material made of said organic polymer materials mixing with hollow particles or solid particles, and said organic polymer material comprises epoxy, vinyl ester resin, UV resin, acrylic resin or cyanate ester resin.

10. The ultrasonic transducer of claim 1, wherein said second acoustic matching layer comprises organic polymer materials or comprises a composite material made of said organic polymer materials mixing with hollow particles or solid particles, and said organic polymer material comprises epoxy, vinyl ester resin, UV resin, polyurethane, silicone, acrylic resin or cyanate ester resin.

11. An ultrasonic transducer, comprising:
a piezoelectric element with an upper surface and a lower surface opposite to each other through said piezoelectric element and a lateral surface connecting said upper surface and said lower surface;
a barrel-shaped carrier, wherein said barrel-shaped carrier comprises an opening, a bottom opposite to said opening and a body connecting said opening and said bottom, and said barrel-shaped carrier is provided with an inner surface and an outer surface opposite to each other through said barrel-shaped carrier, and said inner surface of said barrel-shaped carrier is connected with said upper surface of said piezoelectric element;
a first acoustic matching layer with a first surface and a second surface opposite to each other through said first acoustic matching layer, and said first surface of said first acoustic matching layer is connected with said upper surface of said barrel-shaped carrier; and
a second acoustic matching layer with a third surface and a fourth surface opposite to each other through said second acoustic matching layer, and said third surface of said second acoustic matching layer is connected with said second surface of said first acoustic matching layer, and a glass transition temperature of said second acoustic matching layer is smaller than a glass transition temperature of said first acoustic matching layer.

12. The ultrasonic transducer of claim 11, wherein said glass transition temperature of said first acoustic matching layer is larger than 60° C., and a hardness of said first acoustic matching layer is larger than a hardness of said second acoustic matching layer.

13. The ultrasonic transducer of claim 11, wherein a material of said barrel-shaped carrier is metal, and further comprising a first conductive wire connecting said lower surface of said piezoelectric element and a second conductive wire connecting said inner surface or said outer surface of said barrel-shaped carrier.

14. The ultrasonic transducer of claim 11, further comprising a first damping element, wherein said first damping element encapsulates said piezoelectric element.

15. The ultrasonic transducer of claim 14, further comprising a second damping element, wherein said second damping element encapsulates said first damping element and said barrel-shaped carrier.

16. The ultrasonic transducer of claim 11, wherein a cross-section of said piezoelectric element is in a shape of square, rectangle, circle or polygon.

17. The ultrasonic transducer of claim 11, wherein said first acoustic matching layer comprises organic polymer materials or comprises a composite material made of said organic polymer materials mixing with hollow particles or solid particles, and said organic polymer material comprises epoxy, vinyl ester resin, UV resin, acrylic resin or cyanate ester resin.

18. The ultrasonic transducer of claim 11, wherein said second acoustic matching layer comprises organic polymer materials or comprises a composite material made of said organic polymer materials mixing with hollow particles or solid particles, and said organic polymer material comprises epoxy, vinyl ester resin, UV resin, polyurethane, silicone, acrylic resin or cyanate ester resin.
